(19) United States
(12) Patent Application Publication
(10) Pub. No.: US 2007/0178653 A1
(43) Pub. Date: Aug. 2, 2007

(54) Apparatus and method for manufacturing flat display panel

(75) Inventors: Bong Hyang Kim, Gyeonggi-do (KR); Sang Soo Lee, Gyeonggi-do (KR); Seung Yong Shin, Seoul City (KR); Mun Tae Jung, Daejeon City (KR); Ji Hyun Kim, Gyeonggi-do (KR); Soon Kook Hong, Gyeonggi-do (KR)

Correspondence Address: KED & ASSOCIATES, LLP, P.O. Box 221200, Chantilly, VA, 20153-1200, US

(73) Assignee: LG Electronics Inc.

(21) Appl. No.: 11/655,250

(22) Filed: Jan. 19, 2007

(30) Foreign Application Priority Data
Feb. 2, 2006 (KR) 2006-0010262

(51) Int. Cl. H01L 21/336

(52) U.S. Cl. 438/305

(57) ABSTRACT

Disclosed are an apparatus and method for manufacturing a flat display panel. In forming sustain electrodes and address electrodes, to which electricity is supplied to discharge, on front and rear panels, electrode material, which resides in electrode forming grooves formed on the surface of an electrode roll and each having the same shape as that of electrodes, is transferred on a substrate. The electrode roll transfers the electrode material to the substrate while coming into close contact with and rotating on the substrate. The electrode material adhering to the surface of the electrode roll using a cleaner before the electrode roll transfers the electrode material to the substrate.

### BACKGROUND OF THE INVENTION

1. Field of the Invention

The present invention relates to a flat display panel, and more particularly to an apparatus and method for manufacturing a flat display panel in which a front flat panel and a rear panel are coupled with each other to display an image.

2. Description of the Prior Art

As is generally known in the art, flat display panels include a liquid crystal display panel and a plasma display panel. Between these display panels, the plasma display panel is a kind of image display device in which front and rear panels made from glass substrate are air-tightly coupled with each other to display an image using an electric discharge phenomenon of a gas in the space defined between the front and rear panels.

FIG. 1 illustrates the construction of the main part of a conventional plasma display panel. The drawing exemplifies the rear panel of the plasma display panel. Referring to FIG. 1, an electrode 3 is formed on a substrate 1. The electrode 3 is formed on the substrate 1 to have a predetermined thickness and width. The electrode 3 is to induce an electric discharge in each cell.

A white back 5 is coated on the substrate 1 in such a way as to cover the electrode 3. The white back 5 functions to forwardly reflect visible light which is generated from a fluorescent layer 7 formed in each cell and is directed backward.

In order to form the electrode 3 on the substrate 1, an electrode paste is coated on a glass and is dried in order to remove a solvent, etc. After drying, selective exposure is implemented on the electrode paste. At this time, light is selectively irradiated onto the electrode paste using a mask, etc.

Next, a development process is conducted. That is to say, portions of the electrode paste which are changed or not changed in their properties due to the exposure are selectively removed. After the selective removal of the electrode paste, the shape of the electrode 3 is defined. In general, when the electrode 3 is formed through the exposure and development processes, the electrode 3 has a substantially quadrangular sectional shape.

With the shape of the electrode 3 defined, a baking process is conducted to complete the electrode 3. After the electrode 3 is completed, the white back 5 is applied. Then, partitioning walls are formed on the white back 5, and the fluorescent layer 7 is applied.

The conventional plasma display panel constructed and manufactured as mentioned above has problems as described below.

First, in order to form the electrode 3, five processes, that is, paste application, drying, exposure, development and baking must be implemented. Therefore, as the procedure for forming the electrode 3 requires a lengthy period, productivity is deteriorated.

Further, since the electrode 3 is formed in such a manner that both side surfaces of the electrode 3 are substantially perpendicular to the upper surface of the electrode 3, in the course of applying the white back 5, a curl is likely to be produced in an end of the electrode 3, and as a result, a bubble 9 is likely to be created in the white back 5 as shown in FIG. 1. When the volume of the bubble 9 is abruptly changed due to a high temperature during the operation of the plasma display panel, cracks may be developed in the white back 5, the partitioning walls, etc.

### SUMMARY OF THE INVENTION

Accordingly, the present invention has been made to solve the above-mentioned problems occurring in the prior art, and it is an object of the present invention to form an electrode through a simple procedure.

It is another object of the present invention to apply a substance for covering the electrode formed on the substrate of a flat display panel while not creating a bubble.

It is still another object of the present invention to accurately define a relative position of electrodes formed on a substrate of a flat display panel.

It is still another object of the present invention to miniaturize a structure forming electrodes on a flat display panel.

In order to achieve the above objects of the present invention, there is provided a method for manufacturing a plasma display panel in which electrodes are formed on a substrate, the method comprising the steps of transferring electrode material on a substrate using an electrode roll in which electrode forming grooves elongate in a direction, have the same shape as that of the electrodes, and have inner surfaces, each of which is formed as a curved surface, the electrode roll at least having a shape corresponding to a region of the substrate, drying the electrode material transferred on the substrate in the transferring step; and baking the electrode material dried in the drying step.

The transferring step comprises, a first sub-step for filling the electrode material from an electrode material supplying source to electrode forming grooves of the electrode roll, a second sub-step for removing the electrode material residing on the surface of the electrode roll except for the electrode forming grooves of the electrode roll; and a third sub-step for transferring the electrode material, which resides in the electrode forming grooves, on the substrate by rotating the electrode roll making close contact with the substrate.

In the second sub-step, a cleaner, wound on both a clean roll and a washing roll, is interposed between the clean roll and the electrode roll to come into close contact with the electrode roll in order to remove the electrode material on the surface of the electrode roll, and then is cleaned while passing by the washing roll submerged in washing liquid in a washing bath, the cleaner being used repeatedly.

The electrode roll has a width corresponding to that of the substrate so that one electrode can be formed at a time.

The electrode roll is made of elastic material.

The electrode roll is made of either rubber or silicone.

According to an aspect of the present invention for achieving the objects, there is provided a method for manufacturing a plasma display panel in which electrodes are formed on a substrate, the method comprising the steps of transferring electrode material onto a substrate by rotating an electrode roll coming into close contact with the substrate, the electrode roll having electrode forming grooves which elongate in one direction, have the same shape as that of the electrodes, and have inner surfaces, each of which is formed as a curved surface; drying the electrode material transferred on the substrate in the transferring step; and baking the electrode material dried in the drying step.

According to other aspect of the present invention for achieving the objects, there is provided a flat display panel, the apparatus comprising, an electrode roll having electrode forming grooves impressed in an arch shape on the surface of the electrode roll; an electrode material supplying source for supplying electrode material to the electrode forming grooves of the electrode roll; and a cleaner coming into contact with and moving with respect to the surface of the electrode roll to remove the electrode material residing on the surface of the electrode roll.

The cleaner is wound on both a clean roll and a washing roll, and is moved by either the clean roll or the washing roll.

The cleaner is a closed loop having a width corresponding to that of the electrode roll.

The washing roll moving the cleaner is submerged in washing liquid, which is supplied to a washing bath to wash the cleaner.

The washing roll is partially submerged in the washing liquid.

The cleaner is made of one of non-woven fabric, PET, and PVC.

The electrode roll is made of elastic material.

The electrode roll is made of either rubber or silicone.

### BRIEF DESCRIPTION OF THE DRAWINGS

The above objects and other features and advantages of the present invention will become more apparent after a reading of the following detailed description when taken in conjunction with the drawings, in which:

FIG. 1 is a partial sectional view showing the configuration of the main part of a conventional plasma display panel;

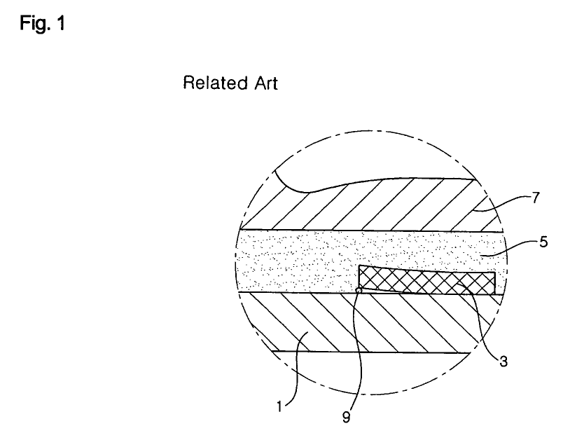

FIG. 2 is an exploded perspective view showing the configuration of a plasma display panel in accordance with an embodiment of the present invention;

FIG. 3 is a partial sectional view showing the configuration of the main part of the plasma display panel in accordance with the embodiment of the present invention;

FIGS. 4A through 4F are sectional views sequentially showing the steps of a method for manufacturing a plasma display panel in accordance with the embodiment of the present invention; and

FIG. 5 is a block diagram illustrating the method for manufacturing a plasma display panel in accordance with the embodiment of the present invention.

### DETAILED DESCRIPTION OF THE PREFERRED EMBODIMENTS

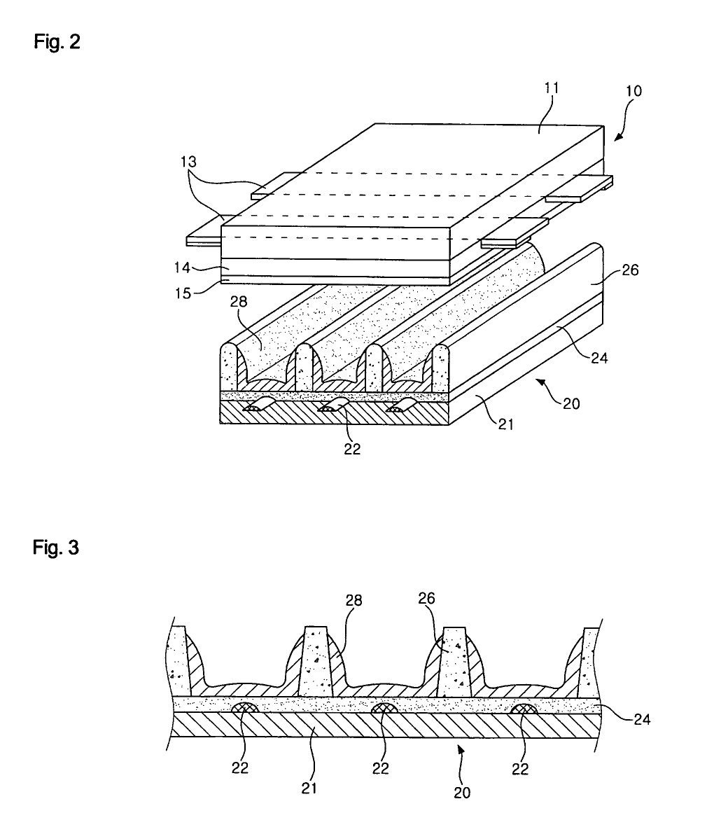

Hereinafter, specific embodiments of a flat display panel and a method for manufacturing the same in accordance with the present invention will be described in detail with reference to FIGS. 2 through 5. For the sake of convenience in explanation, FIG. 2 shows the construction of a three electrode face-discharge type plasma display panel.

In the present invention, a front panel 10 and a rear panel 20 are coupled with each other under a vacuum condition to constitute a plasma display panel. In the front panel 10, a plurality of sustain electrodes 13 for sustain discharge, a dielectric layer 14 for limiting a discharge current, and a protective layer 15 for protecting the dielectric layer 14 are sequentially formed on a first substrate 11.

A second substrate 21 for forming the skeleton of the rear panel 20 has the shape of a plate having a predetermined area. A plurality of address electrodes 22 is formed on the second panel 21 to elongate in one direction. The address electrodes 22 function to induce address discharge between the sustain electrodes 13 of the front panel 10 and the address electrodes 22 of the second panel 21.

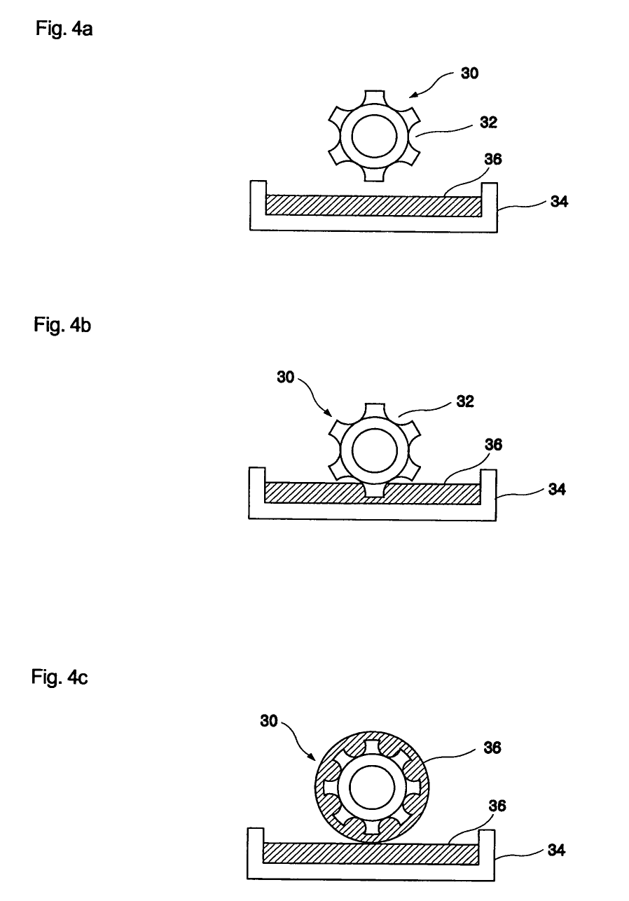

As can be readily seen from FIG. 3, the address electrodes 22 are formed to have the cross-sectional shape of an arch which has a predetermined radius of curvature. That is to say, the surface of each address electrode 22 is formed as a continuous curved surface which has a predetermined curvature. While it is not required that the surface of the address electrode 22 necessarily has a predetermined curvature, it is most convenient for the surface of the address electrode 22 to have a predetermined curvature when forming the address electrodes 22.

A white back 24 is applied on the rear panel 20 to cover the address electrodes 22. The white back 24 functions to forwardly reflect visible light which is generated from a fluorescent layer 28 as will be described later, and is directed backward.

Partitioning walls 26 are formed on the white back 24 at regular intervals. The partitioning walls 26 are formed on the white back 24 to be positioned between two adjoining address electrodes 22. The partitioning walls 26 define discharge spaces in cooperation with the upper surface of the white back 24. Of course, the partitioning walls 26 may be formed on the substrate 21 before applying the white back 24. In this case, after the partitioning walls 26 are formed, the white back 24 is applied on the second substrate 21 in the spaces compartmented by the partitioning walls 26.

The fluorescent layer 28 is applied on the side surface of the portioning walls 26 and the upper surface of the white back 24. The fluorescent layer 28 comprises R, G and B fluorescent substances, which respectively represent red, green and blue, and are alternately applied in the spaces compartmented by the partitioning walls 26.

In the plasma display panel constructed as mentioned above, if a discharge start voltage of 150V˜300V is initially supplied to the sustain electrode 13 and the address electrode 22, which reside in an optional discharge cell, wall electric charges are produced on the inner surfaces of the corresponding discharge space. Thereafter, as an address discharge voltage is supplied to the sustain electrode 13 and the address electrode 22, an address discharge occurs between the sustain electrode 13 and the address electrode 22.

By the address discharge, as an electric field is created in the cell, electrons in a discharge gas are accelerated and come into collision with neutral particles of the gas to be ionized into electrons and ions. Due to continuous collision between the ionized electrons and neutral particles, the neutral particles are ionized into electrons and ions at a gradually increasing speed. As the discharge gas is changed to a plasma state, ultraviolet rays are generated under a vacuum condition and excite the fluorescent layer 28. Then, as visible light is generated, the cell emits light and the display image can be recognized by a person. If a sustain discharge voltage of greater than 150V is supplied to the corresponding sustain electrode 13, a sustain discharge occurs in the corresponding discharge cell, and light emission of the cell is held for a predetermined time.

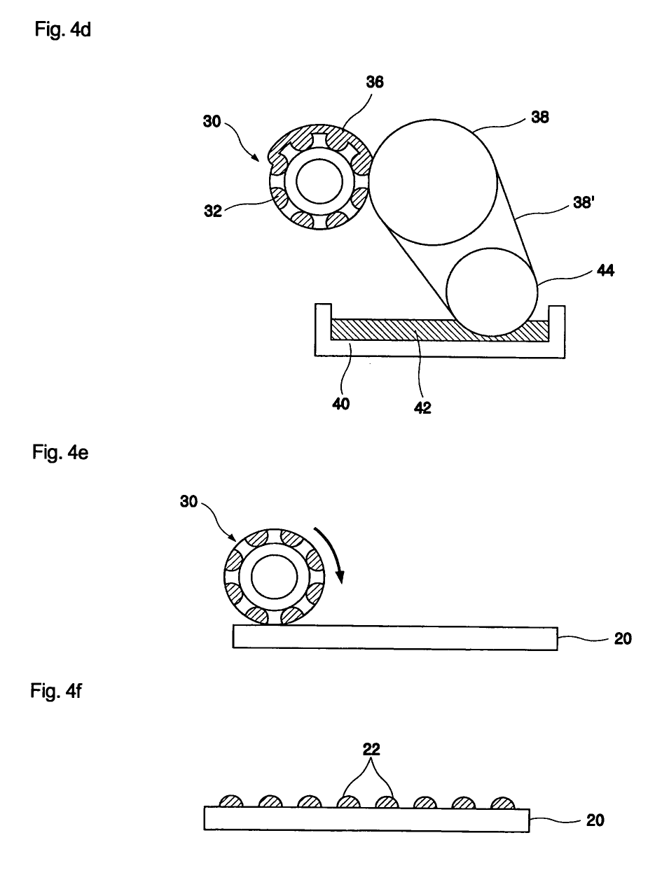

Hereafter, a method for manufacturing a plasma display panel in accordance with the present invention will be described with reference to FIG. 4. Here, for the sake of the convenience in explanation, the descriptions will be presented based on the rear panel.

First, FIG. 4A illustrates the cross-section of an electrode roll 30. Electrode forming grooves 32, each having the same sectional shape as the electrode, for example, the address electrode 22, are defined on the peripheral surface of the electrode roll 30. In the drawing, the electrode forming grooves 32 are illustrated as being cut in a direction perpendicular to the lengthwise direction of the address electrodes 22. As can be readily seen from the cross-sectional view, the electrode forming grooves 32 are formed to have curved bottom surfaces. The electrode forming grooves 32 are defined to be parallel to one another and to elongate in one direction.

It is preferred that the electrode roll 30 have a width corresponding to that of the second panel 21 to be formed with the electrodes 22. Further, it is preferred that the electrode frame 30 be designed such that the electrodes 22 can be formed over the entire area of the single substrate 21. Of course, in the case where the area of the second substrate 21 is very wide, the second substrate 21 can be divided into several regions, and the size of the electrode roll 30 can be appropriately designed so that the electrodes 22 can be sequentially formed in the respective regions. For the reference, the number of electrodes 22, which are formed using the electrode roll 30 at a time, is determined depending on the circumference of the electrode roll 30.

It is preferred that the electrode roll 30 be formed of a material having predetermined elasticity so that an electrode material 36 can be properly transferred to the rear panel 20 in a subsequent process. For example, the electrode roll 30 may be made of soft rubber or silicon. The reason for forming the electrode roll 30 using a material having predetermined elasticity is that the electrode material 36 can be appropriately transferred onto the rear panel 20 through applying pressure to the electrode roll 30. Hence, so long as the electrode material 36 can be appropriately transferred onto the rear panel 20, the electrode roll 30 may be made of metal or rock.

An electrode material supplying source 34 supplies the electrode material 36 to the electrode forming grooves 32 of the electrode roll 30. In other words, a predetermined amount of electrode material 36 is accommodated in the electrode material supplying source 34.

Accordingly, as the electrode roll 30 is dipped into the electrode material 36 in the electrode material supplying source 34 as shown in FIG. 4B, the electrode material 36 adheres to the surface of the electrode roll 30 and is filled in the electrode forming grooves 32. FIG. 4C illustrates a state in which the electrode material 36 adheres to the surface of the electrode roll 30 and is filled in the electrode forming grooves 32.

Next, the electrode material 36, which adheres to the surface of the electrode roll 30, is removed. To this end, a cleaner 38′, wound on a clean roll 38, is brought into close contact with the surface of the electrode roll 30 and rotates in an opposite direction to the electrode roll 30 (see FIG. 4D).

Here, the cleaner 38′ is made of a fabric material such as non-woven fabric, PET, or PVC. The cleaner 38′ is wound on the clean roll 38 and a washing roll 44 while being transferred. Either the clean roll 38 or the washing roll 44 is connected to a driving source which supplies driving force, driving the cleaner 38′. The cleaner 38′ is formed in a loop, and has a width corresponding to that of the electrode roll 30.

For example, the cleaner 38′ may be a belt. The clean roll 38 and the washing roll 44 may be pulleys on which a belt is wound. The washing roll 44 transfers the cleaner 38′ into a washing bath 40 in which a washing liquid 42 is filled, so that the cleaner 38′ is washed. The washing roll 44 is entirely submerged under the washing liquid, or partially submerged under the washing liquid 42, as shown in FIG. 4D.

As described above, when the electrode roll 30 and the clean roll 38 rotate in an opposite direction to each other, the cleaner 38′ comes into contact with the surface of the electrode roll 30. At this time, the electrode material 36 is removed from the surface of the electrode roll 30 by means of the cleaner 38′, while residing in only the electrode forming grooves 32.

FIG. 4E illustrates a process in which the electrode roll 30 is placed on the second substrate 21 and pressure is applied to the electrode frame 30 in order to transfer the electrode material 36 to the second substrate 21. Since the electrode roll 30 is made of a material with a predetermined elasticity, the electrode material 36 residing in the electrode forming grooves 32 is transferred onto the rear panel 20 when desired pressure is applied to the electrode roll 30 to press the rear panel 20.

FIG. 4F shows the state in which the electrode material 36 residing in the electrode forming grooves 32 is transferred onto the second substrate 21. In the state where the electrode material 26 is transferred onto the second substrate 21, when the electrode material 36 is cured by implementing drying and baking processes, the address electrode 22 is completed. Herein, since the drying and baking processes are well known in the art, detailed description of the processes are omitted.

Hereinafter, the operation of the apparatus and method for manufacturing a flat display panel having a configuration as described above according to the present invention will be described in detail.

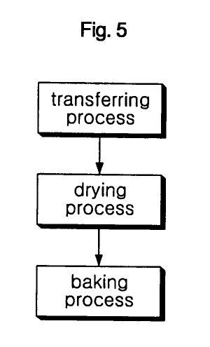

First, in a step of forming the address electrode 22, the address electrodes 22 are formed on the second substrate 21 in such a manner that the electrode roll 30, defined with the electrode forming grooves 32, each having the same cross-sectional shape as the address electrode 22, rotates on the second substrate 21, making close contact with the second substrate 21. After the electrode material 36 is transferred and attached to the second substrate 21, the electrode material 36 is cured through implementing the drying and baking processes, whereby the address electrodes 22 are completed. For reference, FIG. 5 is a block diagram illustrating the method for manufacturing a plasma display panel in accordance with the present invention.

When viewed in its cross-sectional shape, the address electrode 22 has the shape of an arch. That is to say, the surface of the address electrode 22 is formed as a curved surface and more preferably, as a curved surface of a desired curvature. Due to the fact that the surface of the address electrode 22 is formed as a curved surface, when implementing a subsequent process, that is, when applying the white back 24, for example, in the case of the rear panel 20, it is possible to prevent a defect from being caused. In the case of the front panel 10, by forming the surface of the sustain electrode 10 as a curved surface, it is possible to prevent a defect from being caused when applying the dielectric layer 14.

The process for forming the address electrodes 22 on the second substrate 21 using the electrode roll 30 is implemented as described above. Once the address electrodes 22 are formed, the white back 24 is applied on the address electrodes 22 and the second substrate 21.

In the process of applying the white back 24, since the surfaces of the address electrodes 22 are formed as curved surfaces, a curl is not produced, and in particular, even in a portion which is adjacent to the periphery of the address electrode 22, the white back 24 can be reliably applied. Thereafter, the processes for forming the partitioning walls 26 and the fluorescent layer 28 are implemented, whereby the manufacture of the rear panel 20 is completed.

In the meantime, the present invention relates to a flat display panel. While a procedure for manufacturing a plasma display panel was explained with respect to the illustrated embodiments, it can be envisaged that the method of the present invention can be applied to the manufacture of a liquid crystal display panel in the same manner.

Further, while it was described with respect to the illustrated embodiments that only the surfaces of the address electrodes 22 are formed as curved surfaces, it can be readily understood that the surfaces of the sustain electrodes 13 can also be formed as curved surfaces. Depending upon a design condition, only the sustain electrodes 13 can be formed as curved surfaces, and the address electrodes 32 may not be formed as curved surfaces.

As is apparent from the above descriptions, the flat display panel and the method for manufacturing the same according to the present invention, constructed as mentioned above, provide advantages as described below.

First, in the present invention, after an electrode material is filled in electrode forming grooves which are defined on the surface of an electrode roll, each of which has the same sectional shape as an electrode, the electrode material is transferred to a substrate and is then baked to form the electrode. Accordingly, the procedure for forming the electrode on the substrate is greatly simplified.

Specifically, in the present invention, the electrode material is transferred only to necessary portions of the substrate, and there is no electrode material which is applied on the substrate and is then removed, whereby the required amount of electrode material can be minimized. Hence, by the present invention, the manufacturing cost of the flat display panel can be significantly reduced.

Further, in the present invention, the surface of each electrode is formed as a curved surface. Therefore, in the course of applying a substance on the substrate to cover the electrode, a bubble is not created around the electrode, whereby the quality of the flat display panel can be remarkably improved.

According to the present invention, a cleaner is wound on both a clean roll and a washing roll in order to remove electrode material not covered on the electrode forming grooves but the surface of the electrode roll. Further, the cleaner is submerged in and cleaned with washing liquid in a washing bath, thereby making it possible to use the cleaner repeatedly. Hence, generation of waste can be minimized during a process of forming an electrode, resulting in environmentally-friendly implementation of the process. In addition, the cleaner can be used for a relatively long time, thereby reducing manufacturing cost.

According to the present invention, further, electrode forming grooves are formed on the surface of a cylindrical electrode roll in a longitudinal direction. Accordingly, intervals between the electrode forming grooves are regular. By transferring the electrode materials on the substrate using the electrode roll, the electrode materials can be accurately transferred to appropriate positions, resulting in execution of forming electrodes at accurate positions. Accordingly, there is an advantage in that the quality of a flat display panel can be improved.

In addition, according to the present invention, electrode forming grooves are formed in a cylindrical electrode roll, and the electrode material is transferred onto a substrate while the electrode roll rotates on the substrate. Hence, the electrode roll is not required to have an area corresponding to the substrate, whereby the size of the electrode roll can be relatively reduced. As a result, there is an advantage in that the entire size of apparatus can be reduced.

Although preferred embodiments of the present invention have been described for illustrative purposes, those skilled in the art will appreciate that various modifications, additions and substitutions are possible, without departing from the scope and spirit of the invention as disclosed in the accompanying claims.

1. A method of manufacturing a display panel in which electrodes are formed on a substrate, comprising:
filling grooves of an electrode roller with electrode material, wherein the grooves extend in a direction parallel to a longitudinal axis of the electrode roller and wherein the grooves have a shape that corresponds to a shape of the electrodes to be formed;
transferring the electrode material in the grooves of the electrode roller onto a substrate; and
curing the electrode material to form electrodes on the substrate.

2. The method of claim 1, wherein the curing step comprises:
drying the electrode material after it has been transferred onto the substrate; and
baking the electrode material after it has been dried to form electrodes on the substrate.

3. The method of claim 1, wherein the filling step comprises:
applying electrode material from a supplying source onto an outer surface of the electrode roller so that the grooves are filled with the electrode material; and
removing any excess electrode material from the outer surface of the electrode roller so that the electrode material on the electrode roller is substantially only in the grooves.

4. The method of claim 3, wherein the removing step comprises:
moving the electrode roller adjacent a cleaner roller; and
rotating both the electrode roller and the cleaner roller to remove any excess electrode material on the outer surface of the electrode roller.

5. The method of claim 4, wherein a cleaner fabric is wound around the cleaner roller and around a washing roller, wherein the cleaner roller is at least partially submerged in a cleaning bath, and wherein the rotating step results in excess electrode material on the electrode roller being transferred first from the electrode roller to the cleaner fabric, and then from the cleaner fabric into the cleaning bath.

6. The method of claim 1, wherein the electrode roller has a length that corresponds to a length of the substrate such that during the transferring and curing steps, electrodes that extend across substantially the entire length of the substrate are formed.

7. The method of claim 1, wherein the electrode roller is made of an elastic material, and wherein during the transferring step the electrode roller is pressed against the substrate such that it elastically deforms to deposit the electrode material in the grooves onto the substrate.

8. The method of claim 7, wherein the electrode roller is formed of rubber or silicone.

9. The method of claim 1, wherein the filling step comprises filling the electrode material into concave grooves which have a curved shape such that during the transferring and curing steps, electrodes having a curved upper surface are formed on the substrate.

10. An apparatus for manufacturing a display panel, comprising:
means for filling grooves of an electrode roller with electrode material, wherein the grooves extend in a direction parallel to a longitudinal axis of the electrode roller and wherein the grooves have a shape that corresponds to a shape of the electrodes to be formed;
means for transferring the electrode material in the grooves of the electrode roller onto a substrate; and
means for curing the electrode material to form electrodes on the substrate.

11. An apparatus for manufacturing a flat display panel, comprising:
an electrode roller having electrode forming grooves that extend in a direction parallel to a longitudinal axis of the electrode roller, wherein the grooves have a shape that corresponds to a shape of electrodes to be formed on a substrate;
an electrode material supplying source for supplying electrode material into the electrode forming grooves of the electrode roller; and
a cleaner configured to remove excess electrode material from an exterior surface of the electrode roller.

12. The apparatus of claim 11, wherein the cleaner comprises:
a cleaner roller;
a washer roller; and
a cleaner fabric mounted on the cleaner roller and the washer roller.

13. The apparatus of claim 12, wherein the cleaner fabric forms a closed loop and has a width that corresponds to the length of the electrode roller.

14. The apparatus of claim 12, wherein the cleaner roller is configured to be brought adjacent to the electrode roller, and wherein when the cleaner roller and the electrode roller are rotated while the cleaner roller is adjacent the electrode roller, excess electrode material on the electrode roller is transferred to the cleaner fabric.

15. The apparatus of claim 14, wherein the washer roller is at least partially submerged in a cleaning bath such that excess electrode material transferred from the electrode roller onto the cleaner fabric can be removed from the cleaner fabric as the cleaner fabric passes through the cleaning bath.

16. The apparatus of claim 12, wherein the cleaner fabric comprises at least one material selected from the group consisting of non-woven fabric, PET and PVC.

17. The apparatus of claim 11, wherein the electrode roller is made of an elastic material.

18. The apparatus of claim 17, wherein the electrode roller is made of rubber or silicone.

19. The apparatus of claim 11, wherein the grooves in the electrode roller have a concave curved shape such that when electrode material within the grooves is transferred onto a substrate, the electrode material is deposited on the substrate as elongated strips having a curved upper surface.

20. The apparatus of claim 11, wherein the electrode roller is configured to elastically deform when it is pressed against a substrate and rolled across the substrate such that electrode material in the grooves may be deposited onto the substrate.
